(19) United States
(12) Patent Application Publication
(10) Pub. No.: US 2009/0104778 A1
(43) Pub. Date: Apr. 23, 2009

(54) Polishing Composition for CMP and device wafer producing method using the same

(75) Inventors: Yuichi Sakanishi, Hiroshima (JP); Hidetoshi Omori, Hiroshima (JP)

Correspondence Address: BIRCH STEWART KOLASCH & BIRCH, PO BOX 747, FALLS CHURCH, VA, 22040-0747, US

(73) Assignee: DAICEL CHEMICAL INDUSTRIES, LTD.

(21) Appl. No.: 12/285,458

(22) Filed: Oct. 6, 2008

(30) Foreign Application Priority Data
Oct. 18, 2007 (JP) 2007-270807

(51) Int. Cl. H01L 21/304; C09K 13/00

(52) U.S. Cl. 438/692; 252/79.1; 257/E21.239

(57) ABSTRACT

Disclosed is a polishing composition for CMP which contains a polyglycerol derivative (A) represented by following Formula (1):

RO—(C₃H₆O₂)ₙ—H (1)

wherein R represents one selected from a hydroxyl-substituted or unsubstituted alkyl group having one to eighteen carbon atoms, a hydroxyl-substituted or unsubstituted alkenyl or alkapolyenyl group having two to eighteen carbon atoms, an acyl group having two to twenty-four carbon atoms, and hydrogen atom; and “n” denotes an average degree of polymerization of glycerol units and is an integer of 2 to 40; an abrasive (B); and water.

### BACKGROUND OF THE INVENTION

1. Field of the Invention

The present invention relates to a polishing composition for chemical-mechanical planarization (CMP), and a method for producing a device wafer using the polishing composition for CMP. More specifically, it relates to a polishing composition for CMP that is suitable for planarization of surfaces of device wafers typically in the semiconductor industry and of substrates for liquid crystal displays; and to a method for producing a device wafer by polishing the device wafer with the polishing composition for CMP. As used herein “CMP” refers to chemical-mechanical planarization for the planarization of surfaces of, for example, device wafers, by using chemical polishing and mechanical polishing in combination.

2. Description of the Related Art

Current semiconductor devices are intended to have larger and larger packing densities and finer and finer design rules. By way of example, such a semiconductor device is produced in the following manner. A device such as a transistor is formed on a surface of a device wafer by carrying out processes such as patterning of the device wafer by exposure to an ultraviolet ray with a wavelength of about 193 nm, deposition of a film, and etching of the deposited film. Wiring layers are further produced on the surface of the device wafer by repeating processes including: deposition of a film typically by chemical vapor deposition (CVD); planarization of the deposited film; patterning of the deposited film through exposure to light (photolithography); and etching and removing the pattern, to form a circuit. Because a large number of devices such as transistors are formed on the device wafer, a large number of wiring layers are required to wire or connect between the devices. In order to exactly stack these wiring layers according to the design, the surface of each deposited film should be planarized after the film formation process to provide a flat surface without unevenness to thereby facilitate the patterning process through exposure. In addition, an uneven film surface may typically cause disconnection by level difference in the upper layer wiring and local increase of resistance, for example, to cause a break (disconnection) or to reduce a current-carrying capacity. Therefore, it is important that surface planarization should be carried out after the film formation process to remove such unevenness.

CMP is widely used as a planarization technique. It has been known that some common polishing processes in CMP employ nonionic surfactants in order to improve the precision in flatness of the polished surface. See, for example, Japanese Unexamined Patent Application Publication (JP-A) No. 2001-064632 and JP-A No. 2003-176479. However, there are problems in the use of conventional nonionic surfactants such as polyoxyalkylene nonionic surfactants. For example, a surface flaw of the device wafer may be caused; or abrasives and polished debris may be remained on the surface of the device water after cleaning because the surfactants have poor solubility in water, and then, the residues may cause defects. Specifically, there has been found no abrasive that can carry out polishing of a device wafer without surface flaws (surface scratches) and that can be easily removed after polishing, together with polished debris, by cleaning.

### SUMMARY OF THE INVENTION

Accordingly, an object of the present invention is to provide a polishing composition for CMP that can reduce, minimize, or eliminate scratches on the surface of a device wafer through polishing.

Another object of the present invention is to provide a method for producing a device wafer, which includes the step of polishing the surface of the device wafer with the polishing composition for CMP.

After intensive investigations, the present inventors have found that a polishing composition for CMP containing a polyglycerol derivative having a specific structure can carry out polishing of the surface of a device wafer while reducing, minimizing, or eliminating surface scratches of the device wafer, that the polishing composition for CMP can be easily removed from the device wafer surface by cleaning, and that the abrasive in the composition and polished debris do not remain on the device wafer surface after cleaning. The present invention has been made based on these findings.

Specifically, according to the present invention, a polishing composition for CMP, comprises a polyglycerol derivative (A) represented by following Formula (1):

RO—(C₃H₆O₂)ₙ—H (1)

wherein R represents one selected from the group consisting of a hydroxyl-substituted or unsubstituted alkyl group having one to eighteen carbon atoms, a hydroxyl-substituted or unsubstituted alkenyl or alkapolyenyl group having two to eighteen carbon atoms, an acyl group having two to twenty-four carbon atoms, and hydrogen atom; and “n” denotes an average degree of polymerization of glycerol units and is an integer of 2 to 40; an abrasive (B); and water.

Preferably, the polishing composition for CMP preferably has a content of the polyglycerol derivative (A) of 0.01 to 20 percent by weight based on the total weight of the composition.

Preferably, the abrasive (B) is at least one inorganic compound selected from silicon dioxide, aluminum oxide, cerium oxide, silicon nitride, and zirconium oxide.

Further, according to the present invention, a device wafer producing method comprises the step of polishing a device wafer with the polishing composition of the present invention during formation of one or more wirings on the device wafer.

In the polishing composition for CMP of the present invention, a polyglycerol derivative (A) having a specific structure is contained, and the polyglycerol derivative (A) interacts with an abrasive (B) contained in the composition to thereby suppress or avoid aggregating particles of the abrasive (B) each other. This suppresses secondary particles formed by aggregating particles of the abrasive (B) from having a larger average particle diameter. Thus, by polishing a device wafer surface with the polishing composition for CMP, flaws (scratches) of the device wafer surface are reduced, minimized, or eliminated, because the flaws are liable to occur due to the aggregation of the abrasive (B) particles. Additionally, as the polyglycerol derivative (A) is highly dispersive in water, the abrasive and debris after polishing can be easily removed from the device wafer surface by cleaning.

These and other objects, features, and advantages of the present invention will be more fully understood from the following description of preferred embodiments with reference to the attached drawing.

### BRIEF DESCRIPTION OF THE DRAWING

FIG. 1 is a schematic side view of an exemplary polishing machine for use in a method for producing a device wafer according to the present invention.

### DESCRIPTION OF THE PREFERRED EMBODIMENTS

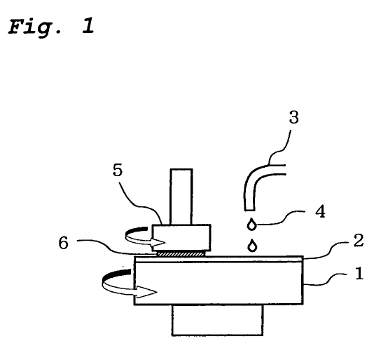

Some embodiments of the present invention will be illustrated in detail below with reference to the attached drawing. FIG. 1 is a schematic side view of an exemplary polishing machine for use in a method for producing a device wafer according to an embodiment of the present invention.

With reference to FIG. 1, a polishing pad 2 is arranged on a platen 1, and a device wafer 6 is pressed to the surface of the polishing pad 2 by the action of a polishing head 5. A polishing composition for CMP 4 is fed from a polishing composition dispenser 3 to the vicinity of the polishing head 5; the platen 1 and the polishing head 5 are rotated; and thus the surface of the device wafer 6 is polished.

Polyglycerol Derivative (A)

Polyglycerol derivatives (A) for use in the present invention are represented by following Formula (1):

RO—(C₃H₆O₂)ₙ—H (1)

wherein R represents a hydroxyl-substituted or unsubstituted alkyl group having one to eighteen carbon atoms, a hydroxyl-substituted or unsubstituted alkenyl or alkapolyenyl group having two to eighteen carbon atoms, an acyl group having two to twenty-four carbon atoms, or hydrogen atom; and “n” denotes an average degree of polymerization of glycerol units and is an integer of 2 to 40.

Exemplary hydroxyl-substituted or unsubstituted alkyl groups having one to eighteen carbon atoms as R include linear or branched alkyl groups such as methyl, ethyl, propyl, pentyl, hexyl, heptyl, 2-ethylhexyl, octyl, isooctyl, decyl, isodecyl, dodecyl, tetradecyl, oleyl, isododecyl, myristyl, isomyristyl, cetyl, isocetyl, stearyl, and isostearyl groups; and these groups with hydroxyl-substitution. Among them, preferred are linear or branched alkyl groups having twelve to eighteen carbon atoms, such as dodecyl group and isostearyl group.

Exemplary hydroxyl-substituted or unsubstituted alkenyl groups having two to eighteen carbon atoms as R include linear or branched alkenyl groups such as vinyl, propenyl, allyl, hexenyl, 2-ethylhexenyl, and oleyl groups; and these groups with hydroxyl-substitution. Among them, preferred are linear or branched alkenyl groups having eight to eighteen carbon atoms, such as hexenyl group and oleyl group.

Exemplary hydroxyl-substituted or unsubstituted alkapolyenyl groups having two to eighteen carbon atoms as R include alkadienyl groups such as linoleyl group; alkatrienyl groups such as linolenyl group; and alkatetraenyl groups; and these groups with hydroxyl-substitution.

Exemplary acyl groups having two to twenty-four carbon atoms as R include aliphatic acyl groups and aromatic acyl groups. Exemplary aliphatic acyl groups include acetyl, propionyl, butyryl, isobutyryl, stearoyl, and oleoyl groups. Exemplary aromatic acyl groups include benzoyl, toluoyl, and naphthoyl groups.

Among them, alkyl groups, acyl groups, and hydrogen atom are preferred as R, of which more preferred are linear alkyl groups (of which methyl, ethyl, propyl, decyl, and stearyl group are preferred, and methyl group is more preferred); aliphatic acyl groups (of which acetyl, butyl, stearoyl, and oleoyl groups are preferred, and acetyl and oleoyl groups are more preferred); and hydrogen atom.

The number “n” in Formula (1) represents an average degree of polymerization of glycerol. For example, when a polyglycerol ether is prepared from an alcohol and glycidol (2,3-epoxy-1-propanol; available typically as “Glycidol” from Daicel Chemical Industries, Ltd., Japan), the average degree of polymerization “n” can be easily varied by adjusting the molar ratio of the reactant alcohol to glycidol. The number “n” is an integer of 2 to 40, and is preferably an integer of 4 to 20, and more preferably an integer of 4 to 10. When a polyglycerol derivative have a number “n” of less than 2, the polyglycerol derivative may have insufficient solubility in water, so that a device wafer surface after polishing may not be satisfactorily cleaned with the polyglycerol derivative. In contrast, when a polyglycerol derivative have a number “n” of more than 40, the polyglycerol derivative may have excessively high solubility in water, so that it show insufficient dispersibility of abrasive (B) in water. In addition, a polyglycerol derivative of this type may be liable to show significantly low foaming ability and workability of the polishing composition.

The “C₃H₆O₂” moiety in the parenthesis in Formula (1) can have both of structures represented by following Formulae (2) and (3):

—CH₂—CHOH—CH₂O— (2)

—CH(CH₂OH)CH₂)— (3)

The weight-average molecular weight of a polyglycerol derivative (A) in the present invention is preferably 200 to 3000, more preferably 400 to 1500, and further preferably 400 to 800. A polyglycerol derivative (A) having a weight-average molecular weight within the above range may help to improve surface activity and workability of the polishing composition. Such weight-average molecular weights herein are measured by gel permeation chromatography (GPC).

Exemplary polyglycerol derivatives (A) in the present invention include compounds represented by following formulae:

C₁₂H₂₅O—(C₃H₆O₂)₄—H

C₁₂H₂₅O—(C₃H₆O₂)₁₀—H

HO—(C₃H₆O₂)₁₀—H

HO—(C₃H₆O₂)₂₀—H

CH₂═CH—CH₂—O—(C₃H₆O₂)₆—H

CH₃—(C₁₇H₃₄)—O—(C₃H₆O₂)₄—H

CH₃—(C₁₇H₃₄)—O—(C₃H₆O₂)₁₀—H

Polyglycerol derivatives (A) in the present invention may be prepared according to various processes. Exemplary processes for preparing polyglycerol derivatives (A) include (1) a process of adding 2,3-epoxy-1-propanol (available typically as “Glycidol” from Daicel Chemical Industries, Ltd., Japan) to an aliphatic alcohol corresponding to R in the presence of an alkaline catalyst; and (2) a process of condensing a polyglycerol with an alkyl halide, a carboxylic acid or a reactive derivative thereof, such as an acid halide or acid anhydride, or a polyol.

In the process (1) for preparing polyglycerol derivatives (A), exemplary alkaline catalysts include sodium hydroxide, potassium hydroxide, lithium hydroxide, metal sodium, and sodium hydride. Exemplary aliphatic alcohols corresponding to R include primary alcohols, secondary alcohols, and tertiary alcohols. Aliphatic alcohols corresponding to R may each have two or more hydroxyl groups. Specifically, they may be any of monohydric alcohols, dihydric alcohols, and polyhydric alcohols.

Representative primary alcohols as aliphatic alcohols corresponding to R include saturated or unsaturated aliphatic primary alcohols having about one to eighteen carbon atoms, such as methanol, ethanol, 1-propanol, allyl alcohol, 1-butanol, 2-methyl-1-propanol, 1-hexanol, 1-octanol, 1-decanol, lauryl alcohol, 1-hexadecanol, 2-buten-1-ol, ethylene glycol, 1,3-propanediol (trimethylene glycol), glycerol, hexamethylene glycol, and pentaerythritol; saturated or unsaturated alicyclic primary alcohols such as cyclohexylmethyl alcohol and 2-cyclohexylethyl alcohol; and aromatic primary alcohols such as benzyl alcohol, 2-phenylethyl alcohol, and cinnamic alcohol.

Representative secondary alcohols as aliphatic alcohols corresponding to R include saturated or unsaturated aliphatic secondary alcohols having about three to eighteen carbon atoms, such as 2-propanol, s-butyl alcohol, 2-pentanol, 3-pentanol, 3,3-dimethyl-2-butanol, 2-octanol, 4-decanol, 2-hexadecanol, 2-penten-4-ol, glycerol, and vicinal diols including 1,2-propanediol, 2,3-butanediol, and 2,3-pentanediol; secondary alcohols whose carbon atom bearing hydroxyl group further has an aliphatic hydrocarbon group and an alicyclic hydrocarbon group (e.g., a cycloalkyl group), such as 1-cyclopentylethanol and 1-cyclohexylethanol; saturated or unsaturated alicyclic secondary alcohols (including bridged secondary alcohols) having about three to eighteen members, such as cyclobutanol, cyclopentanol, cyclohexanol, cyclooctanol, cyclododecanol, 2-cyclohepten-1-ol, and 2-cyclohexen-1-ol; and aromatic secondary alcohols such as 1-phenylethanol, 1-phenylpropanol, 1-phenylmethylethanol, and diphenylmethanol.

Representative tertiary alcohols as aliphatic alcohols corresponding to R include saturated or unsaturated aliphatic tertiary alcohols having about four to eighteen carbon atoms, such as t-butyl alcohol and t-amyl alcohol; secondary alcohols whose carbon atom bearing hydroxyl group further has an aliphatic hydrocarbon group and an alicyclic hydrocarbon group (e.g., a cycloalkyl group or a bridged hydrocarbon group), such as 1-cyclohexyl-1-methylethanol; tertiary alcohols in which one carbon atom constituting an alicyclic ring (e.g., a cycloalkane ring or a bridged carbon ring) has hydroxyl group and an aliphatic hydrocarbon group, such as 1-methyl-1-cyclohexanol; aromatic tertiary alcohols such as 1-phenyl-1-methylethanol; and heterocyclic tertiary alcohols such as 1-methyl-1-(2-pyridyl)ethanol.

In the process (2) for preparing polyglycerol derivatives (A), exemplary preferred polyglycerols to be used include commercially available products under the trade names of, for example, “Polyglycerol 04”, “Polyglycerol 06”, “Polyglycerol 10”, and “Polyglycerol X” (Daicel Chemical Industries, Ltd., Japan). Exemplary alkyl halides corresponding to the alkyl groups as R include alkyl chlorides, alkyl bromides, and alkyl iodides. Exemplary carboxylic acids corresponding to the acyl groups as R include acetic acid, propionic acid, butyric acid, valeric acid, and lauric acid. Exemplary polyols corresponding to R include ethylene glycol, propylene glycol, 1,3-propane diol (trimethylene glycol), glycerol, xylitol, and sorbitol.

The polishing composition for CMP of the present invention may contain two or more kinds of polyglycerol derivatives (A). Further, the polyglycerol derivatives (A), represented by Formula (1), comprised in the polishing composition for CMP of the present invention may contain polyglycerol diether and/or polyglycerol diester each corresponding to polyglycerol, polyglycerol ether, and/or polyglycerol ester. In this case, it is preferred that the total content of the monoether and monoester is 75% or more and the total content of the diether and diester is 5% or less. It is more preferred that the total content of the monoether and the monoester is 90% or more and the total content of the diether and diester is 1% or less. The total content of the monoether and monoester and the total content of the diether and diester are determined as areal ratios obtained by eluting products through high-performance liquid chromatography, determining peak areas of the products with a differential refractometer, and calculating the peak area ratio. Polyglycerol derivatives having less than 75% of the total content of the monoether and monoester may show insufficient solubility in water.

A polishing composition for CMP according to the present invention has a content of polyglycerol derivatives (A) of preferably 0.01 to 20 percent by weight, more preferably 0.05 to 15 percent by weight, and further preferably 0.1 to 10 percent by weight based on the total weight of the polishing composition for CMP. When a polishing composition for CMP has a content of polyglycerol derivatives (A) of less than 0.01 percent by weight, the aggregation of the abrasive (B) particles may not sufficiently avoid or suppress, and secondary particles having a larger average particle diameter due to the aggregation of the abrasive (B) particles may be cause. Therefore, the polishing composition for CMP, if used for polishing a device wafer surface, may be liable to cause scratches on the device wafer surface. In contrast, when a polishing composition for CMP has a content of polyglycerol derivatives (A) of more than 20 percent by weight, the polishing composition may have an excessively high viscosity, and this may impair the workability in polishing of a device wafer surface.

Abrasive (B)

Exemplary abrasives (B) for use herein may be known or common abrasives, of which preferred is at least one inorganic compound selected from silicon dioxide, aluminum oxide, cerium oxide, silicon nitride, and zirconium oxide.

The silicon dioxide is not particularly limited by its preparation technique, and silicon dioxide prepared according to any technique, such as colloidal silica or fumed silica, may be used.

Exemplary aluminum oxides include α-alumina, δ-alumina, θ-alumina, κ-alumina, and any aluminum oxides in other forms. Additionally, an aluminum oxide called “fumed alumina” according to its preparation technique can also be used.

Exemplary cerium oxides include trivalent or tetravalent hexagonal cerium oxide, equiaxial cerium oxide, and face-centered cubic cerium oxide, and any of them may be used.

Exemplary silicon nitrides include α-silicon nitride, β-silicon nitride, amorphous silicon nitride, and any silicon nitrides in other forms.

Exemplary zirconium oxides include any zirconia oxides such as monoclinic zirconium oxide, tetragonal zirconium oxide, and amorphous zirconium oxide. Additionally, a zirconium oxide called “fumed zirconia” according to its preparation technique can also be used.

The silicon dioxide has an average particle diameter as determined according to the Brunauer-Emmett-Teller method (BET method) of preferably 0.005 to 0.5 μm and more preferably 0.01 to 0.2 μm. The aluminum oxide, silicon nitride, and zirconium oxide may each have an average particle diameter determined according to the BET method of preferably 0.01 to 10 μm and more preferably 0.05 to 3 μm. The cerium oxide may have an average particle diameter as determined scanning-electron-microscopically of preferably 0.01 to 10 μm and more preferably 0.05 to 3 μm. An abrasive (B) having an average particle diameter of larger than the above range may cause a rough surface of the polished article and may be liable to cause issues such as scratching. An abrasive (B) having an average particle diameter of smaller than the above range may be liable to invite an excessively low polishing rate, thus being unpractical.

Each of different abrasives may be used alone or in combination as the abrasive (B). The amount of abrasives (B) can be arbitrarily adjusted according typically to the use, and the amount in terms of content of abrasives (B) may be about 0.1 to 50 percent by weight, is preferably about 0.5 to 40 percent by weight, and more preferably about 1 to 35 percent by weight based on the total amount of the polishing composition for CMP. A polishing composition for CMP having a content of abrasives (B) within the above range may have a viscosity suitable for polishing and may have a satisfactory polishing rate.

Polishing composition for CMP

The polishing composition for CMP according to the present invention contains the polyglycerol derivative (A) and the abrasive (B), as well as water. The water is not particularly limited, and exemplary waters include ultra-pure water, ion-exchanged water, distilled water, tap water (city water), and water for industrial use. The amount of water may be arbitrarily adjusted according to necessity, and the amount in terms of water content may be about 40 to 99 percent by weight, and is preferably about 45 to 95 percent by weight, and more preferably about 55 to 90 percent by weight based on the total amount of the polishing composition for CMP. A polishing composition for CMP having water content within this range may have a viscosity suitable for polishing and may have a satisfactory polishing rate.

The polishing composition for CMP may further contain additives according to necessity. Exemplary additives include rust-preventives (anticorrosives), viscosity modifiers, surfactants, chelating agents, pH adjusters, preservatives, and antifoaming agents.

The rust-preventives is not particularly limited, and exemplary rust-preventives include rust-preventives described in “Additives for Petroleum Products” (published on Aug. 10, 1974, SAIWAI SHOBO). Specific examples of rust-preventives include aliphatic or alicyclic amines having two to sixteen carbon atoms, including alkylamines such as octylamine, alkenylamines such as oleylamine, and cycloalkylamines such as cyclohexylamine, and ethylene oxide (1 to 2 moles) adducts of these aliphatic or alicyclic amines having two to sixteen carbon atoms; alkanolamines having two to four carbon atoms, such as monoethanolamine, diethanolamine, and monopropanolamine, and ethylene oxide (1 to 2 moles) adducts of these alkanolamines having two to four carbon atoms; salts of aliphatic carboxylic acids having eighteen to twenty carbon atoms, such as oleic acid and stearic acid, with alkali metals (e.g., Li, Na, K, Rb, and Cs) or alkaline earth metals (e.g., Ca, Sr, Ba, and Mg); sulfonates such as petroleum sulfonates; phosphatic esters such as lauryl phosphate; silicates such as sodium silicate and calcium silicate; phosphates such as sodium phosphate, potassium phosphate, and sodium polyphosphate; nitrites such as sodium nitrite; and benzotriazole. Each of different rust-preventives may be used alone or in combination.

The amount of the rust-preventives may be suitably adjusted according typically to use, and the amount of the rust-preventives is, for example, about 0.01 to 5 percent by weight, preferably about 0.05 to 3 percent by weight, and more preferably about 0.1 to 2 percent by weight, based on the total weight of the polishing composition for CMP.

The viscosity modifiers help to adjust the viscosity of the polishing composition for CMP and are used herein for diluting the polishing composition for CMP. Exemplary viscosity modifiers include monohydric water-miscible alcohols such as methanol, ethanol, and propanol; dihydric or higher water-miscible alcohols such as ethylene glycol, propylene glycol, butylene glycol, glycerol, and polyethylene glycols with a degree of polymerization of 2 to 50. Each of different viscosity modifiers may be used alone or in combination.

The amount of viscosity modifiers may be suitably adjusted according typically to use, and the amount in terms of content of viscosity modifiers is, for example, about 0.1 to 30 percent by weight, preferably about 0.5 to 20 percent by weight, and more preferably about 1 to 10 percent by weight, based on the total weight of the polishing composition for CMP.

Exemplary surfactants include nonionic surfactants other than the polyglycerol derivatives (A); anionic surfactants; cationic surfactants; and amphoteric surfactants. Each of different surfactants may be used alone or in combination.

Exemplary nonionic surfactants other than the polyglycerol derivatives (A) include aliphatic alcohol alkylene oxide adducts (C₈-C₂₄ in the aliphatic alcohol moiety, C₂-C₈ in the alkylene moiety, and the degree of polymerization of alkylene oxide of 2-100); polyoxyalkylene higher fatty acid esters (C₂-C₈ in the alkylene moiety, the degree of polymerization of alkylene oxide of 2-100, and C₈-C₂₄ in the fatty acid moiety), such as polyethylene glycol monostearate (the degree of polymerization of ethylene oxide of 20) and polyethylene glycol distearate(the degree of polymerization of ethylene oxide of 30); polyhydric (di- to deca- or higher hydric) alcohols (C₂-C₁₀) higher fatty acid (C₈-C₂₄) esters, such as glycerol monostearate, ethylene glycol monostearate, sorbitan monolaurate, and sorbitan dioleate; polyoxyalkylene polyhydric (di- to deca- or higher hydric) alcohol higher fatty acid esters (C₂-C₈ in the alkylene moiety, the degree of polymerization of alkylene oxide of 2-100, C₂-C₁₀ in the alcohol moiety, and C₈-C₂₄ in the fatty acid moiety), such as polyoxyethylene sorbitan monolaurate (the degree of polymerization of ethylene oxide of 10) and polyoxyethylene methyl glucoside dioleate(the degree of polymerization of ethylene oxide of 50); polyoxyalkylene alkyl phenyl ethers(C₂-C₈ in the alkylene moiety, the degree of polymerization of alkylene oxide of 2-100, and C₁-C₂₂ in the alcohol moiety); polyoxyalkylene alkyl amino ethers (C₂-C₈ in the alkylene moiety, the degree of polymerization of alkylene oxide of 1-100, and C₈-C₂₄ in the alkyl moiety); and alkyl (C₈-C₂₄) dialkyl (C₁-C₆) amine oxides, such as lauryldimethylamine oxide.

Exemplary anionic surfactants include C₈-C₂₄ hydrocarbon (ether) carboxylic acids and salts thereof, such as sodium polyoxyethylene lauryl ether acetate (the degree of polymerization of ethylene oxide of 2-100); salts of C₈-C₂₄ hydrocarbon (ether) sulfates, such as sodium lauryl sulfate, sodium polyoxyethylene lauryl sulfate (the degree of polymerization of ethylene oxide of 2-100), polyoxyethylene lauryl sulfate triethanolamine (the degree of polymerization of ethylene oxide of 2-100), and sodium polyoxyethylene coconut oil fatty acid monoethanolamide sulfate (the degree of polymerization of ethylene oxide of 2-100); salts of C₈-C₂₄ hydrocarbon (ether) sulfonates, such as sodium dodecylbenzenesulfonate and disodium polyoxyethylene lauryl sulfosuccinate (the degree of polymerization of ethylene oxide of 2-100); as well as disodium polyoxyethylene lauroylethanolamide sulfosuccinate (the degree of polymerization of ethylene oxide of 2-100), coconut oil fatty acid methyltaurine sodium salts, coconut oil fatty acid sarcosine sodium salts, coconut oil fatty acid sarcosine triethanolamine, N-coconut oil fatty acid acyl-L-glutamic acid triethanolamine, sodium N-coconut oil fatty acid acyl-L-glutamate, and sodium lauroylmethyl-β-alanine.

Exemplary cationic surfactants include quaternary ammonium salt type cationic surfactant, such as stearyltrimethylammonium chloride, behenyltrimethylammonium chloride, distearyldimethylammonium chloride, and lanolin fatty acid aminopropylethyldimethylammonium ethylsulfates; and amine salt type cationic surfactants, such as diethylaminoethylamide lactate stearate, dilaurylamine hydrochloride, and oleylamine lactate.

Exemplary amphoteric surfactants include betaine type amphoteric surfactants such as coconut oil fatty acid amidopropyldimethylaminoacetic betaines, lauryldimethylaminoacetic betaine(dodecylbetaine), 2-alkyl-N-carboxymethyl-N-hydroxyethylimidazilinium betaines, lauryl hydroxysulfobetaine, sodium lauroyl amidoethyl hydroxyethyl carboxymethyl betaine hydroxypropyl; amino acid type amphoteric surfactants such as sodium β-lauryl aminopropionate.

The amount of surfactants is suitably adjusted according typically to use, and the content of surfactants is, for example, about 0.01 to 5 percent by weight, preferably about 0.05 to 3 percent by weight, and more preferably about 0.1 to 1 percent by weight based on the total weight of the polishing composition for CMP.

Exemplary chelating agents include sodium polyacrylate, sodium ethylenediaminetetraacetate, sodium succinate, and sodium 1-hydroxyethane-1,1-diphosphonate.

Exemplary pH adjusters include acids such as acetic acid, boric acid, citric acid, oxalic acid, phosphoric acid, and hydrochloric acid; and alkalis such as ammonia, sodium hydroxide, and potassium hydroxide.

Exemplary preservatives include alkyl diaminoethyl glycine hydrochlorides. Exemplary antifoaming agents include silicones, long-chain alcohols having four to sixteen carbon atoms, fatty acid esters whose fatty acid moiety has four to sixteen carbon atoms, and metallic soaps.

The amounts of such additives, if used, may be suitably adjusted within ranges not adversely affecting the characteristic properties of the polishing composition for CMP, and contents of respective additives are, for example, about 0.001 to 10 percent by weight, preferably about 0.05 to 5 percent by weight, and more preferably about 0.01 to 2 percent by weight, based on the total amount of the polishing composition for CMP.

Polishing composition for CMP according to the present invention may be prepared by mixing the above-mentioned components with a known or common mixing apparatus. When abrasives with poor dispersibility are used, a planetary mixer that exhibits a high shearing force may be used. The order of adding the components (materials) is not particularly limited. When silicon dioxide is used as the abrasive (B), the pH of the composition is preferably adjusted with a pH adjuster such as an alkali, because such silicon dioxide shows stable dispersion at a pH of 9 or more. The viscosity of the polishing composition for CMP may be either adjusted or not. The resulting polishing compositions for CMP are in the form of slurries, and whose particle size distributions may be measured typically with a laser scattering (laser diffraction) particle size analyzer.

The polishing composition for CMP according to the present invention contains a polyglycerol derivative (A) having a specific structure, in which the polyglycerol derivative (A) interacts with an abrasive (B) to suppress or avoid the aggregation of particles of the abrasive (B) to thereby suppress the secondary particles of the abrasive (B) from having a larger average particle diameter due to aggregation. Accordingly, the polishing composition for CMP, if used for polishing surfaces of device wafers and liquid crystal display substrates, can realize efficient and smooth polishing of the surfaces. Thus, surface scratches of the device wafers and liquid crystal display substrates are reduced, minimized, or eliminated, because scratches may occur in proportional to sizes of the secondary particles derived from aggregated particles of the abrasive (B). Additionally, since the polyglycerol derivative (A) is highly dispersive in water, the abrasive and polished debris can be easily removed by cleaning after polishing from the surfaces of device wafers and liquid crystal display substrates.

Method for Producing Device Wafer

A device wafer may be produced in the following manner. A device such as a transistor is formed on a surface of a device wafer composed typically of silicon, germanium, or gallium-arsenic: by a device formation process comprising steps such as a step of patterning the device wafer through exposure to an ultraviolet ray with a wavelength of about 193 nm, a step of depositing a film, and a step of etching the deposited film. Further, a circuit is formed on the device by a process of stacking wiring layers by repeating a wiring formation process including the steps of depositing a film typically by chemical vapor deposition (CVD), planarizating the deposited film, patterning the film through exposure to light (photolithography), and etching to remove the pattern. The device wafer producing method of the present invention is characterized by using the polishing composition for CMP of the present invention in the step of planarizating the deposited film.

Exemplary polishing machines for use in the method for producing a device wafer are not particularly limited and include rotary polishing machines and belt-type polishing machines. An exemplary representative polishing machine is illustrated in FIG. 1. In an exemplary polishing process, the platen 1 and the polishing head 5 are respectively rotated; and, while feeding the polishing composition for CMP 4 from the polishing composition dispenser 3 to the vicinity of the polishing head 5, the surface of the device wafer 6 is pressed to the surface of the polishing pad 2 arranged on the platen 1 to polish the surface of the device wafer 6 to thereby planarize the surface with high precision. The polishing composition for CMP 4 may be fed in an amount of about 50 to 1000 ml/min. The polishing pad 2 is preferably composed of a foam typically of a regular polyurethane. The polishing process is preferably carried out at a temperature of room temperature (1° C. to 30° C.), a pressure of 1 to 10 psi (about 7 to 69 kPa), and a number of revolutions of the polishing head 5 and platen 2 of 10 to 100 rpm, for a duration of about 10 seconds to 5 minutes.

In the method for producing a device wafer of the present invention, films, deposited on enormous numbers of devices such as transistors and arranged on the surface of the device wafer, can be planarized without scratching. Thus, wirings of the devices such as transistors can be exactly stacked in accordance with the design to give multilayer wiring layers. Additionally, the method for producing a device wafer eliminates unevenness of the film surfaces and thereby gives a device wafer with higher reliability, because such unevenness of the film surfaces invites, for example, disconnection by level difference in the upper layer wiring and local increase of resistance to cause a break (disconnection) and to reduce the current-carrying capacity. Additionally, semiconductor devices with finer structures can be produced by cutting the resulting device wafer.

The present invention will be illustrated in further detail with reference to several examples below. It should be noted, however, these are illustrated only by way of example and never construed to limit the scope of the present invention.

Materials used in Examples below are as follows:

(1) An adduct of 1 mole of lauryl alcohol with 4 mole of 2,3-epoxy-1-propanol (“Glycidol” supplied by Daicel Chemical Industries, Ltd., Japan), (hereinafter also referred to as “Polyglycerol Derivative (A1)”);

(2) An adduct of 1 mole of lauryl alcohol with 10 mole of 2,3-epoxy-1-propanol (“Glycidol” supplied by Daicel Chemical Industries, Ltd., Japan), (hereinafter also referred to as “Polyglycerol Derivative (A2)”);

(3) An adduct of 1 mole of lauryl alcohol with 6 mole of 2,3-epoxy-1-propanol (“Glycidol” supplied by Daicel Chemical Industries, Ltd., Japan), (hereinafter also referred to as “Polyglycerol Derivative (A3)”);

(4) An adduct of 1 mole of isostearyl alcohol with 10 mole of 2,3-epoxy-1-propanol (“Glycidol” supplied by Daicel Chemical Industries, Ltd., Japan), (hereinafter also referred to as “Polyglycerol Derivative (A4)”);

(5) An adduct of 1 mole of glycerol with 9 mole of 2,3-epoxy-1-propanol (“Glycidol” supplied by Daicel Chemical Industries, Ltd., Japan), (hereinafter also referred to as “Polyglycerol Derivative (A5)”);

(6) An adduct of 1 mole of glycerol with 19 mole of 2,3-epoxy-1-propanol (“Glycidol” supplied by Daicel Chemical Industries, Ltd., Japan), (hereinafter also referred to as “Polyglycerol Derivative (A6)”).

Materials used in Comparative Examples below are as follows:

(7) An adduct of 1 mole of ethylene glycol with 48 moles of ethylene oxide further added with 38 moles of propylene oxide (hereinafter also referred to as “Polyoxyalkylene Derivative (A1)”);

(8) An adduct of 1 mole of ethylene glycol with 32 moles of ethylene oxide further added with 20 moles of propylene oxide (hereinafter also referred to as “Polyoxyalkylene Derivative (A2)”);

(9) An adduct of 1 mole of lauryl alcohol with 10 moles of ethylene oxide (hereinafter also referred to as “Polyoxyalkylene Derivative (A3)”); and

(10) An adduct of 1 mole of lauryl alcohol with 20 moles of ethylene oxide (hereinafter also referred to as “Polyoxyalkylene Derivative (A4)”).

Preparation Example (Preparation of Abrasive Slurry)

An abrasive slurry with an abrasive concentration of 20 percent by weight was prepared by dispersing colloidal silica (average particle diameter of primary particles: 0.035 μm) and cerium oxide (average particle diameter of primary particles: 0.2 μm) in water with a mixer (“T.K. HOMO MIXER”, PRIMIX Corporation, Japan).

### EXAMPLE 1

Polishing composition for CMP 1 was prepared by mixing 4.0 parts by weight of Polyglycerol Derivative (A1), 20 parts by weight of the abrasive slurry prepared in Preparation Example (preparation of abrasive slurry), 0.2 part by weight of aqueous ammonia as a pH adjuster, and 200 ml of ion-exchanged water using a mixer (“T.K. HOMO MIXER”, PRIMIX Corporation, Japan).

### EXAMPLE 2

Polishing composition for CMP 2 was prepared by mixing 4.0 parts by weight of Polyglycerol Derivative (A2), 20 parts by weight of the abrasive slurry prepared in Preparation Example (preparation of abrasive slurry), 0.2 part by weight of aqueous ammonia as a pH adjuster, and 200 ml of ion-exchanged water using a mixer (“T.K. HOMO MIXER”, PRIMIX Corporation, Japan).

### EXAMPLE 3

Polishing composition for CMP 3 was prepared by mixing 4.0 parts by weight of Polyglycerol Derivative (A3), 20 parts by weight of the abrasive slurry prepared in Preparation Example (preparation of abrasive slurry), and 200 ml of ion-exchanged water using a mixer (“T.K. HOMO MIXER”, PRIMIX Corporation, Japan).

### EXAMPLE 4

Polishing composition for CMP 4 was prepared by mixing parts by weight of Polyglycerol Derivative (A4), 20 parts by weight of the abrasive slurry prepared in Preparation Example (preparation of abrasive slurry), and 200 ml of ion-exchanged water using a mixer (“T.K. HOMO MIXER”, PRIMIX Corporation, Japan).

### EXAMPLE 5

Polishing composition for CMP 5 was prepared by mixing parts by weight of Polyglycerol Derivative (A5), 20 parts by weight of the abrasive slurry prepared in Preparation Example (preparation of abrasive slurry), and 200 ml of ion-exchanged water using a mixer (“T.K. HOMO MIXER”, PRIMIX Corporation, Japan).

### EXAMPLE 6

Polishing composition for CMP 6 was prepared by mixing 4.0 parts by weight of Polyglycerol Derivative (A6), 20 parts by weight of the abrasive slurry prepared in Preparation Example (preparation of abrasive slurry), 0.2 part by weight of aqueous ammonia as a pH adjuster, and 200 ml of ion-exchanged water using a mixer (“T.K. HOMO MIXER”, PRIMIX Corporation, Japan).

### COMPARATIVE EXAMPLE 1

Polishing composition for CMP 7 was prepared by mixing 4.0 parts by weight of Polyoxyalkylene Derivative (A1), 20 parts by weight of the abrasive slurry prepared in Preparation Example (preparation of abrasive slurry), 0.2 part by weight of aqueous ammonia as a pH adjuster, and 200 ml of ion-exchanged water using a mixer (“T.K. HOMO MIXER”, PRIMIX Corporation, Japan).

### COMPARATIVE EXAMPLE 2

Polishing composition for CMP 8 was prepared by mixing 4.0 parts by weight of Polyoxyalkylene Derivative (A2), 20 parts by weight of the abrasive slurry prepared in Preparation Example (preparation of abrasive slurry), 0.2 part by weight of aqueous ammonia as a pH adjuster, and 200 ml of ion-exchanged water using a mixer (“T.K. HOMO MIXER”, PRIMIX Corporation, Japan).

### COMPARATIVE EXAMPLE 3

Polishing composition for CMP 9 was prepared by mixing 4.0 parts by weight of Polyoxyalkylene Derivative (A3), 20 parts by weight of the abrasive slurry prepared in Preparation Example (preparation of abrasive slurry), and 200 ml of ion-exchanged water using a mixer (“T.K. HOMO MIXER”, PRIMIX Corporation, Japan).

### COMPARATIVE EXAMPLE 4

Polishing composition for CMP 10 was prepared by mixing 4.0 parts by weight of Polyoxyalkylene Derivative (A4), 20 parts by weight of the abrasive slurry prepared in Preparation Example (preparation of abrasive slurry), and 200 ml of ion-exchanged water using a mixer (“T.K. HOMO MIXER”, PRIMIX Corporation, Japan).

Evaluation Tests

Polishing compositions for CMP 1 to 10 prepared according to Examples 1 to 6 and Comparative Examples 1 to 4 were examined by the following techniques.

Polishing Test

A 8-inch diameter silicon wafer having a film formed by thermal oxidation of silicon on the wafer surface was used as an article to be polished. The film has a thickness of 1 μm. A one-side polishing machine (“EPO 113”, Ebara Corporation) and a polishing pad (“IC 1000”, Rodel Inc.) were used herein.

Polishing Conditions:
Polishing pressure: 5 psi
Platen rotation speed: 60 rpm
Wafer rotation speed: 50 rpm
Amount of polishing composition for CMP: 150 ml/min.
Polishing duration: 2 min.

The above-mentioned silicon wafer was polished under the above-mentioned polishing conditions, and then, the polished silicon wafer was cleaned with pure water and dried. The numbers of scratches of 0.2 μm or more in length on the polished silicon wafer surface were counted, and polishing properties were evaluated according to the following criteria. The scratches were observed with the “Surfscan SP-1” (produced by KLA-Tencor).

Criteria:
Less than five scratches: Excellent
Five or more and less than twenty scratches: Good
Twenty or more and less than thirty scratches: Fair
Thirty or more scratches: Poor

Filterability Test

The polishing compositions for CMP 1 to 10 used in the polishing test were collected respectively, and one liter of each of the collected polishing compositions for CMP was filtrated through a 1-μm membrane filter (47 mm in diameter) at a filter-inlet pressure (a pressure of the filter on the original composition side: p1) of 2 kg/cm² (2×10⁻³ Pa). A filter-outlet pressure (a pressure of the filter on the filtrate side: p2) was measured with the “Manostar Gage WO81 FN100” (Yamamoto Electric Works Co., Ltd.), and a pressure drop was calculated according to the following equation.

Pressure drop(%)=[(p−p2)/p1]×100

Filterability was determined according to the following criteria.

The pressure drop is less than 10%: Excellent

The pressure drop is 10% or more and less than 50%: Good

The pressure drop is 50% or more and less than 70%: Fair

The pressure drop is 70% or more, or the composition causes plugging and can not be filtered: Poor

The results are shown in Table 1 below.

TABLE 1

| | | Polishing | |
|---|---|---|---|
| | | with | |
| | | reduced | Filter- |
| | | scratching | ability |
| Example 1 | Polishing composition for CMP 1 | Excellent | Excellent |
| Example 2 | Polishing composition for CMP 2 | Excellent | Excellent |
| Example 3 | Polishing composition for CMP 3 | Good | Excellent |
| Example 4 | Polishing composition for CMP 4 | Excellent | Good |
| Example 5 | Polishing composition for CMP 5 | Good | Good |
| Example 6 | Polishing composition for CMP 6 | Good | Good |
| Com. Ex. 1 | Polishing composition for CMP 7 | Fair | Fair |
| Com. Ex. 2 | Polishing composition for CMP 8 | Fair | Fair |
| Com. Ex. 3 | Polishing composition for CMP 9 | Poor | Poor |
| Com. Ex. 4 | Polishing composition for CMP 10 | Poor | Poor |

Table 1 demonstrates that polishing of a silicon wafer surface with each of the polishing compositions for CMP 1 to 6 according to embodiments of the present invention (Examples 1 to 6) can be carried out with less scratching (less than twenty scratches) on the silicon wafer surface. In contrast, polishing of a silicon wafer surface with each of the polishing compositions for CMP 7 to 10 (Comparative Examples 1 to 4) using polyoxyalkylene derivatives instead of the polyglycerol derivatives (A) causes scratching (twenty or more scratches) on the silicon wafer surface.

Additionally, the data in the filterability tests demonstrate that the polishing compositions for CMP 1 to 6 (Examples 1 to 6) show superior filterability with a pressure drop of less than 50% upon filtering through the membrane filter. In contrast, the polishing compositions for CMP 7 to 10 (Comparative Examples 1 to 4) using polyoxyalkylene derivatives instead of the polyglycerol derivatives (A) show unsatisfactory filterability with a pressure drop of 50% or more.

These results demonstrate that, in the polishing composition for CMP of the present invention, the average particle diameter of secondary particles of the abrasive (B) particles is reduced and the occurrence of scratches caused by the aggregation of the abrasive (B) particles is reduced or eliminated by containing polyglycerol derivatives (A) that help to prevent or reduce the aggregation of the abrasive. In contrast, the polishing compositions for CMP using the polyoxyalkylene derivatives instead of the polyglycerol derivatives (A) cause higher occurrence of scratches, because these polishing compositions for CMP do not suppress the aggregation of the abrasive (B) particles in the compositions, and secondary particles derived from the aggregated abrasive (B) particles have a larger average particle diameter, and these larger secondary particles cause more scratches.

1. A composition for chemical mechanical planarization, the composition comprising:
a polyglycerol derivative (A) represented by following Formula (1):
RO—(C₃H₆O₂)ₙ—H (1)
wherein R represents one selected from the group consisting of a hydroxyl-substituted or unsubstituted alkyl group having one to eighteen carbon atoms, a hydroxyl-substituted or unsubstituted alkenyl or alkapolyenyl group having two to eighteen carbon atoms, an acyl group having two to twenty-four carbon atoms, and hydrogen atom; and “n” denotes an average degree of polymerization of glycerol units and is an integer of 2 to 40;
an abrasive (B); and
water.

2. The composition of claim 1, wherein a content of the polyglycerol derivative (A) is 0.01 to 20 percent by weight based on the total weight of the composition.

3. The composition of claim 1 or 2, wherein the abrasive (B) is at least one inorganic compound selected from the group consisting of silicon dioxide, aluminum oxide, cerium oxide, silicon nitride, and zirconium oxide.

4. A device wafer producing method, comprising the step of polishing a device wafer with the composition of claim 1 or 2 during formation of a wiring on the device wafer.
